(19) United States
(12) Patent Application Publication
(10) Pub. No.: US 2024/0413042 A1
(43) Pub. Date: Dec. 12, 2024

(54) PACKAGE STRUCTURE AND METHOD FOR FORMING SAME

(71) Applicant: JCET Group Co., Ltd., Wuxi (CN)

(72) Inventors: Shuo LIU, Wuxi (CN); Chen XU, Wuxi (CN); JianYong WU, Wuxi (CN)

(73) Assignee: JCET Group Co., Ltd., Wuxi (CN)

(21) Appl. No.: 18/736,444

(22) Filed: Jun. 6, 2024

(30) Foreign Application Priority Data
Jun. 9, 2023 (CN) 202310686053.2

(51) Int. Cl. H01L 23/367; H01L 23/498; H01L 23/528

(52) U.S. Cl. CPC H01L 23/3675; H01L 23/49816; H01L 23/5283

(57) ABSTRACT

A package structure and a method for forming the same are provided. The package structure includes: a first substrate having an upper surface and a lower surface that are opposite to each other, wherein at least one trench is defined in the first substrate, the trench extending through a portion of the upper surface of the first substrate; a first chip mounted onto the upper surface of the first substrate on a side of the trench, wherein the first chip electrically connects to the first substrate; a heat sink lid including a horizontal heat sink plate and a first vertical pin and at least one second vertical pin, wherein a length of the second vertical pin is greater than a length of the first vertical pin, and the heat sink lid is mounted onto the upper surface of the first substrate.

### CROSS-REFERENCE TO RELATED APPLICATION

The present application is based upon and claims priority to Chinese Patent Application No. CN202310686053.2, filed on Jun. 9, 2023, the entire disclosure of which is incorporated herein by reference for all purposes.

### TECHNICAL FIELD

The present disclosure relates to the technical field of semiconductor packaging, and in particular, relates to a package structure and a method for forming the same.

### BACKGROUND

Conventional packaging technologies have evolved from early 2D packaging towards 2.5D stacked packaging and 3D stacked packaging to achieve better performance, smaller volume, and lower power consumption.

As one form of 3D stacked packaging, package on package (POP) stacking typically involves upper and lower substrates stacked on top of each other, with corresponding semiconductor chips mounted on each substrate. With the rapid development of communication systems and artificial intelligence, there is an increase in computational demand and consequently in the number of high-power semiconductor chips to accommodate these requirements. This poses thermal management challenges for stacked package structures. Currently, it is common practice to attach heat sinks to the upper substrate surface of stacked package structures to dissipate the heat generated by high-power semiconductor chips. However, conventional stacked package structures still tend to warp, and the efficiency of heat dissipation remains to be improved.

### SUMMARY

Some embodiments of the present disclosure provide a method for forming a package structure. The method includes:
providing a first substrate, wherein the first substrate has an upper surface and a lower surface that are opposite to each other, and at least one trench is defined in the first substrate, the trench extending through a portion of the upper surface of the first substrate;
providing a first chip;
mounting the first chip onto the upper surface of the first substrate on a side of the trench, wherein the first chip is electrically connected to the first substrate;
providing a heat sink lid, wherein the heat sink lid includes a horizontal heat sink plate, and a first vertical pin and at least one second vertical pin that protrude from a surface of the horizontal heat sink plate, a length of the second vertical pin being greater than a length of the first vertical pin; and
mounting the heat sink lid onto the upper surface of the first substrate, wherein a bottom surface of the first vertical pin of the heat sink lid is attached to the upper surface of the first substrate, and a bottom end of the second vertical pin of the heat sink lid is buried in a corresponding trench.

Some embodiments of the present disclosure further provide a package structure. The package structure includes:
a first substrate having an upper surface and a lower surface that are opposite to each other, wherein at least one trench is defined in the first substrate, the trench extending through a portion of the upper surface of the first substrate;
a first chip mounted onto the upper surface of the first substrate on a side of the trench, wherein the first chip is electrically connected to the first substrate;
a heat sink lid including a horizontal heat sink plate and a first vertical pin and at least one second vertical pin that protrude from a surface of the horizontal heat sink plate, wherein a length of the second vertical pin is greater than a length of the first vertical pin, the heat sink lid is mounted onto the upper surface of the first substrate, a bottom surface of the first vertical pin of the heat sink lid is attached to the upper surface of the first substrate, and a bottom end of the second vertical pin of the heat sink lid is buried in a corresponding trench.

### BRIEF DESCRIPTION OF THE DRAWINGS

FIG. 1 is a schematic structural diagram of a process for providing a first substrate in forming a package structure according to some embodiments of the present disclosure;

FIG. 2 is a schematic structural diagram of a process for forming at least one trench in the first substrate in forming the package structure according to some embodiments of the present disclosure;

FIG. 3 is a schematic structural diagram of a process for providing a first chip in forming the package structure according to some embodiments of the present disclosure;

FIG. 4 is a schematic structural diagram of a process for providing a heat sink lid in forming the package structure according to some embodiments of the present disclosure;

FIG. 5 is a schematic structural diagram of a process for mounting the heat sink lid onto an upper surface of the first substrate in forming the package structure according to some embodiments of the present disclosure;

FIG. 6 is a schematic structural diagram of a process for providing a second chip in forming the package structure according to some embodiments of the present disclosure; and

FIG. 7 is a schematic structural diagram of a process for providing a second substrate in forming the package structure according to some embodiments of the present disclosure.

### DETAILED DESCRIPTION

The embodiments of the present disclosure provide a package structure and a method for forming the same. The package structure includes: a first substrate having an upper surface and a lower surface that are opposite to each other, wherein at least one trench is defined in the first substrate, the trench extending through a portion of the upper surface of the first substrate; a first chip, wherein the first chip includes a functional surface and a back surface that are opposite to each other, the first chip is mounted onto the upper surface of the first substrate on a side of the trench, and the first chip is electrically connected to the first substrate; a heat sink lid including a horizontal heat sink plate and a first vertical pin and at least one second vertical pin that protrude from a surface of the horizontal heat sink plate, wherein a length of the second vertical pin is greater than a length of the first vertical pin, the heat sink lid is mounted onto the upper surface of the first substrate, a bottom surface of the first vertical pin of the heat sink lid is attached to the upper surface of the first substrate, a bottom end of the second vertical pin of the heat sink lid is buried in a corresponding trench, and a bottom surface of the horizontal heat sink plate of the heat sink lid is attached to the back surface of the first chip. In the package structure according to the present disclosure, at least one trench is defined in the first substrate, and the heat sink lid includes a horizontal heat sink plate and a first vertical pin and at least two second vertical pin that protrude from a surface of the horizontal heat sink plate. A length of the second vertical pin is greater than a length of the first vertical pin. The heat sink lid is mounted onto the upper surface of the first substrate, a bottom surface of the first vertical pin of the heat sink lid is attached to the upper surface of the first substrate, a bottom end of the second vertical pin of the heat sink lid is buried the corresponding trench, and a bottom surface of the horizontal heat sink plate of the heat sink lid is attached to the back surface of the first chip. According to the present disclosure, heat dissipation is achieved by the horizontal heat sink plate in the heat sink lid. Furthermore, since the bottom end of the second vertical pin in the heat sink lid extends into and is buried in the corresponding trench in the first substrate, in one aspect, presence of the second vertical pins increases channels for heat dissipation, and improves heat dissipation efficiency; and in another aspect, collaboration between the trench and the second vertical pin overcomes or balances warpage of the first substrate. Further, the second vertical pin is buried in the corresponding trench in the first substrate, such that the heat sink lid is better secured, and hence the horizontal heat sink plate is strongly bonded to the back surface of the first chip. This addresses the problem that heat dissipation capabilities are reduced due to insufficient coverage of the thermal bonding adhesive (the third thermal bonding adhesive) caused by a stress effect between the horizontal heat sink plate and the back surface of the first chip.

The specific embodiments of the present disclosure are described in detail hereinafter with reference to the accompanying drawings. In the description of the embodiments of the present disclosure, for ease of illustration, the schematic structural views are not partially enlarged according to a typical scale, and the schematic views are given for exemplary purpose only, which do not limit the protection scope of the present disclosure. In addition, in practice, a three-dimension spatial size in terms of length, width, and depth needs to be included.

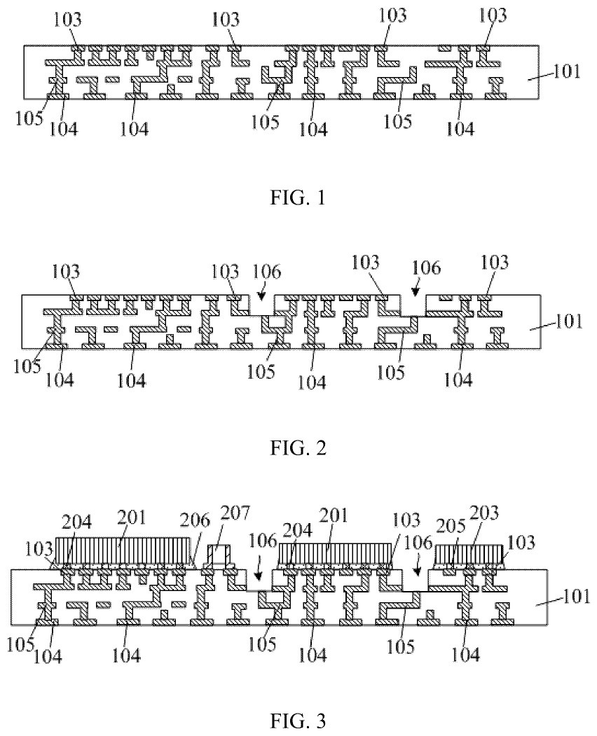

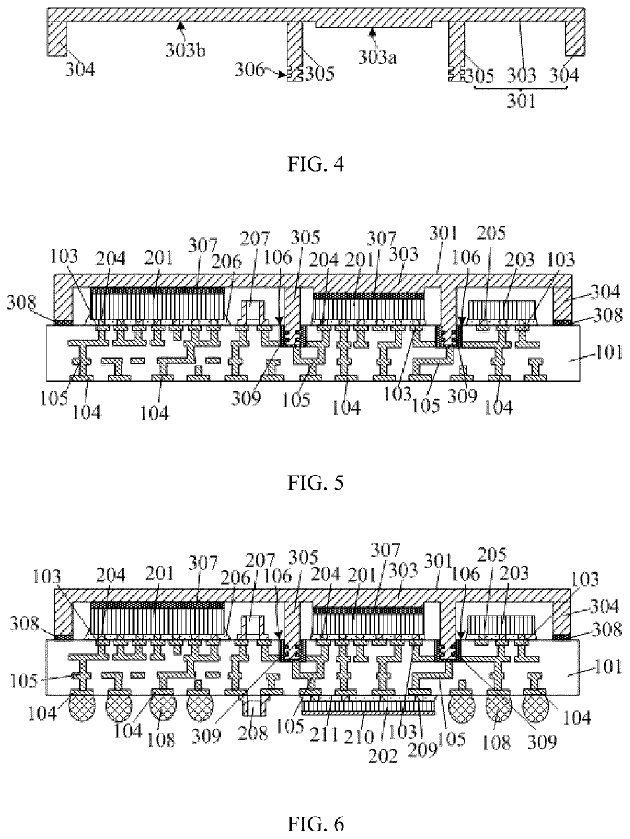

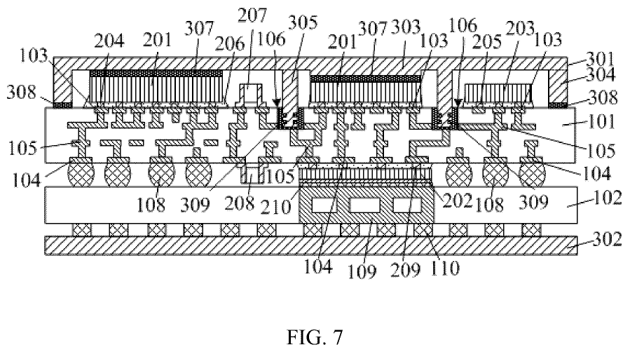

Some embodiments of the present disclosure provide a method for forming a package structure. Hereinafter, the method is described with reference to the accompanying drawings. Hereinafter, description is given with reference to FIG. 1 to FIG. 7. FIG. 1 is a schematic structural diagram of a process for providing a first substrate in forming a package structure according to some embodiments of the present disclosure. FIG. 2 is a schematic structural diagram of a process for forming at least one trench in the first substrate in forming the package structure according to some embodiments of the present disclosure. FIG. 3 is a schematic structural diagram of a process for providing a first chip in forming the package structure according to some embodiments of the present disclosure. FIG. 4 is a schematic structural diagram of a process for providing a heat sink lid in forming the package structure according to some embodiments of the present disclosure. FIG. 5 is a schematic structural diagram of a process for mounting the heat sink lid onto an upper surface of the first substrate in forming the package structure according to some embodiments of the present disclosure. FIG. 6 is a schematic structural diagram of a process for providing a second chip in forming the package structure according to some embodiments of the present disclosure. FIG. 7 is a schematic structural diagram of a process for providing a second substrate in forming the package structure according to some embodiments of the present disclosure.

Referring to FIG. 1, a first substrate 101 is provided. The first substrate 101 has an upper surface and a lower surface that are opposite to each other.

A first chip is subsequently mounted onto the upper surface of the first substrate 101, and a second chip is subsequently mounted onto the lower surface of the first substrate 101.

In some embodiments, a first trace 105 is arranged in the first substrate 101, and an upper pad 103 and a lower pad 104 that are connected to the first trace 105 are respectively arranged on the upper surface and the lower surface of the first substrate 101. The first trace 105, the lower pad 103, and the upper pad 104 are all made of a metal. The metal may be one or more of aluminum, nickel, tin, tungsten, platinum, copper, titanium, chromium, tantalum, gold, or silver. The first trace 105 may be a single-layer or multi-layer structure. The first trace 105 may include a metal trace or a metal plug or a via interconnect structure (or a through-hole interconnect structure) electrically connected to the metal trace.

In some embodiments, the first substrate 101 may be a resin substrate, a ceramic substrate, a glass substrate, a silicon substrate, a printed circuit board (PCB).

Referring to FIG. 2, at least one trench 106 is formed in the first substrate 101. The trench 106 extends through a portion of the upper surface of the first substrate 101.

The trench 106 is subsequently configured to bury a bottom end of a second vertical pin 305 of a heat sink lid 301 to increase channels for heat sink, and meanwhile improve or balance warpage of the first substrate 101 (the warpage of the first substrate 101 may be caused by a stress produced in the package structure).

The trench 106 is formed in the first substrate 101 by etching the first substrate 101.

One or a plurality of trenches 106 are arranged. When a plurality of trenches 106 are arranged, one second vertical pin 305 of the heat sink lid 301 is buried in each of the trenches 106. The number of trenches 106 is consistent with the number of second vertical pins 305 to be buried.

The plurality of trenches 106 are positioned in the first substrate 101 on one or more sides of a flip-mounting region (or mounting region) of the first chip.

A depth of the trench 106 is less than a thickness of the first substrate 101, and a size of the trench 106 is greater than a size of the bottom end of the second vertical pin of the heat sink lid.

In some embodiments, the trench 106 is a circular trench or a square trench.

In some embodiments, the trench 106 exposes a portion of the first trace 105, and thus subsequently when the second vertical pin 305 (referring to FIG. 6) of the heat sink lid 301 is buried in the trench 106, heat produced in the portion of the first trace 105 and the first substrate 101 may be easily released via the second vertical pin 305 or may be conducted to a horizontal heat sink plate 303 (referring to FIG. 6) of the heat sink lid 301 via the second vertical pin 305 for release, such that heat dissipation efficiency is improved.

Referring to FIG. 3, a first chip 201 is provided, wherein the first chip 201 includes a functional surface and a back surface that are opposite to each other; the functional surface of the first chip 201 is mounted onto the upper surface of the first substrate 101 on a side of the trench 106, wherein the first chip 201 is electrically connected to the first substrate 101.

The first chip 201 is a high-power chip, which produces a large amount of heat during running. Therefore, the heat produced by the first chip 201 needs to be released to prevent electrical performance of the package structure from being affected by the heat. In some embodiments, the first chip 201 may be a logic chip or a memory chip. One or a plurality of first chips 201 may be arranged. When a plurality of first chips 201 are arranged, the plurality of first chips 201 may include a logic chip and a memory chip. In one specific embodiment, the logic chip may include a gate array, a cell-based array, an embedded array, an application-specific integrated circuit (ASIC), a field-programmable gate array (FPGA), a complex programmable logic device (CPLD), a central processing unit (CPU), a microprocessor units (MPU), a microcontroller unit (MCU), an integrated circuit (IC), an application processor (AP), a display driver IC (DDI), a radio frequency (RF) chip, a power management IC, or a complementary metal-oxide-semiconductor (CMOS) image sensor. In one specific embodiment, the memory chip may include a volatile memory chip, such as a dynamic random access memory (DRAM) or a static RAM (SRAM), or a non-volatile memory chip, such as a flash memory (Flash), a phase change RAM (PRAM), a magnetoresistive RAM (MRAM), a ferroelectric RAM (FeRAM) or a resistive RAM (ReRAM).

In some embodiments, the first chip 201 includes a functional surface and a back surface that are opposite to each other. An integrated chip (not illustrated) is formed in the first chip 201. A pad (not illustrated) is arranged on the functional surface of the first chip 201. The pad is electrically connected to the integrated circuit. A protruded first solder bump 204 is formed on a surface of the pad of the first chip 201. In some embodiments, the first solder bump 204 may be a solder boss or includes a metal bump or a solder boss on a top surface of the metal bump. In some embodiments, the pad is made of one or more of aluminum, nickel, tin, tungsten, platinum, copper, titanium, chromium, tantalum, gold, silver, the material of the metal bump is one or more of aluminum, nickel, tin, tungsten, platinum, copper, titanium, chromium, tantalum, gold, silver, and the material of the solder bump is one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

When the first chip 201 is flip-mounted onto the upper surface of the first substrate 101, the first solder bump 204 on the functional surface of the first chip 201 is soldered to the upper pad 103 on the upper surface of the first substrate 101.

The first chip 201 is flip-mounted on the upper surface of the first substrate 101 on a side of the trench 106 or between the plurality of trenches 106.

In some embodiments, when a plurality of first chips 201 are arranged, the plurality of first chips 201 have the same thickness or different thicknesses.

In some embodiments, a passive device 207 is further mounted onto the upper surface of the first substrate 101. The passive device 207 is electrically connected to a portion of the first trace 105 in the first substrate 101. The passive device 207 may be one or more of a resistor, a capacitor, an inductor, a converter, a taper, a matching network, a resonator, a filter, a mixer, or a switch.

In some embodiments, a third chip 203 is further mounted onto the upper surface of the first substrate 101. The third chip 203 is electrically connected to a portion of the first trace 105 in the first substrate 101. The third chip 203 is a low-power chip or a chip free of heat dissipation.

In some embodiments, an underfill layer 206 may be filled between the first chip 201 and the upper surface of the first substrate 101 and between the third chip 203 and the upper surface of the first substrate 101. The underfill layer 206 may be made of a silicon-based resin material, a thermoplastic resin material, a heat-cured resin material, or an ultraviolet-cured resin material, and a process for forming the underfill layer 206 includes a glue dispensing process.

Referring to FIG. 4, a heat sink lid 301 is provided. The heat sink lid 301 includes a horizontal heat sink plate 303, and a first vertical pin 304 and at least one second vertical pin 305 that protrude from a surface of the horizontal heat sink plate 303. A length of the second vertical pin 305 is greater than a length of the first vertical pin 304.

The heat sink lid 301 is subsequently mounted onto the upper surface of the first substrate for heat dissipation of the chip and the substrate.

A bottom surface of the horizontal heat sink plate 303 is subsequently attached to the back surface of the first chip. In some embodiments, when the plurality of first chips flip-mounted onto the upper surface of the first substrate have the same thickness, different regions of the horizontal heat sink plate 303 have the same or consistent thickness. In some other embodiments, when the plurality of first chips flip-mounted onto the upper surface of the first substrate have different thicknesses, depending on the different thicknesses of the plurality of first chips, a plurality of regions of the horizontal heat sink plate 303 may have different thicknesses, for example, a region 303a and a region 303b on the horizontal heat sink plate 303 in FIG. 4 may be different, the thickness of the region 303a is greater than the thickness of the region 303b. During subsequent mounting of the horizontal heat sink plate 303, the region 303a having a larger thickness is attached to the back surface of the first chip 201 (referring to FIG. 5) having a smaller thickness, and the region 303b having a smaller thickness is attached to the back surface of the first chip 201 (referring to FIG. 5), such that by one heat sink lid 301, synchronous heat dissipation is achieved for the first chips 201 with different thicknesses that are flip-mounted.

The first vertical pin 304 is mainly configured to support the heat sink lid, and a bottom of the first vertical pin 304 is subsequently attached to the upper surface of the first substrate. In some embodiments, the first vertical pin 304 is annular.

One or a plurality of second vertical pins 305 may be arranged. The length of the second vertical pin 305 is greater than the length of the first vertical pin 304, and a difference between the length of the second vertical pin 305 and the length of the first vertical pin 304 is equal to or less than the depth of the trench. In this way, during subsequent mounting of the heat sink lid 301, the bottom end of the second vertical pin 305 extends into and is buried in the corresponding trench 106 (referring to FIG. 5) in the first substrate 101. In one aspect, presence of the second vertical pins 305 increases channels for heat dissipation, and improves heat dissipation efficiency. In another aspect, collaboration between the trench 106 and the second vertical pin 305 overcomes or balances warpage of the first substrate 101. Further, the second vertical pin 305 is buried in the corresponding trench 106 in the first substrate 101, such that the heat sink lid 301 is better secured, and hence the horizontal heat sink plate 303 of the heat sink lid 301 is strongly bonded to the back surface of the first chip 201 (referring to FIG. 5). This addresses the problem that heat dissipation capabilities are reduced due to insufficient coverage of the thermal bonding adhesive (the third thermal bonding adhesive, referring to FIG. 5) caused by a stress effect between the horizontal heat sink plate 303 of the heat sink lid 301 and the back surface of the first chip 201.

In some embodiments, at least one recess 306 (referring to FIG. 4) is defined in the bottom end of the second vertical pin 305. When the bottom end of the second vertical pin 305 of the heat sink lid 301 is subsequently buried in the corresponding trench 106 in the first substrate 101 via the second thermal bonding adhesive 309 (referring to FIG. 5), the second thermal bonding adhesive 309 wraps a side wall of the bottom end and a bottom surface of the second vertical pin 305, and fills the trench 106 and the recess 306, such that a contact area between the bottom end of the second vertical pin 305 and the second thermal bonding adhesive 309 is increased. In this way, a bonding force between the bottom end of the second vertical pin 305 and the second thermal bonding adhesive 309 is further enhanced, and the rate of thermal conduction of the second vertical pin 305 is increased.

The heat sink lid 301 is made of a material with high thermal conductivity. In some embodiments, the material with high thermal conductivity includes a metal (for example, copper, aluminum, gold, nickel, steel, or stainless steel) or a carbon-containing material (for example, graphite, graphene, or carbon nanotube).

Referring to FIG. 5, the heat sink lid 301 is mounted onto the upper surface of the first substrate 101. A bottom surface of the first vertical pin 304 of the heat sink lid 301 is attached to the upper surface of the first substrate 101, the bottom end of the second vertical pin 305 of the heat sink lid 301 is buried in the corresponding trench 106, and the bottom surface of the horizontal heat sink plate 303 of the heat sink lid 301 is attached to the back surface of the first chip 201.

In some embodiments, the bottom surface of the first vertical pin 304 of the heat sink lid 301 is attached to the upper surface of the first substrate 101 via a thermal bonding adhesive 308, the bottom end of the second vertical pin 305 of the heat sink lid 301 is buried in the corresponding trench 106 via the second thermal bonding adhesive 309, and the bottom surface of the horizontal heat sink plate 303 of the heat sink lid 301 is attached to the back surface of the first chip 201 via a third thermal bonding adhesive 307.

The first thermal bonding adhesive 308, the second thermal bonding adhesive 309, and the third thermal bonding adhesive 307 have thermal conductive and adhesive properties.

In some embodiments, the first thermal bonding adhesive 308, the second thermal bonding adhesive 309, and the third thermal bonding adhesive 307 may be made of a thermal interface material (TIM).

In other embodiments, the bottom surface of the first vertical pin 304 of the heat sink lid 301 may be attached to the upper surface of the first substrate 101 only via a bonding layer. The bonding layer may have a thermally conductive filler or may not have a thermally conductive filler.

In some embodiments, referring to FIG. 6, the method further includes: providing a second chip 202, wherein the second chip 202 includes a functional surface and a back surface that are opposite to each other, wherein a second solder bump 209 protrudes from the functional surface of the second chip 202; and mounting the functional surface of the second chip 202 onto the lower surface of the first substrate 101, and soldering the second solder bump 209 to the lower pad 104 on the lower surface of the first substrate 101.

The second chip 202 is also a chip which needs heat dissipation. A thickness of the second chip 202 is less than the thickness of the first chip 201. That is, the chip which is subsequently thin and needs heat dissipation is mounted onto the lower surface of the first substrate 101 to reduce the size of the package structure. In this way, a stress of the package structure is balanced, while a thickness of the package structure may not be increased.

In some embodiments, the second chip 202 may be a logic chip or a memory chip. One or a plurality of second chips 202 may be arranged. When a plurality of second chips 202 are arranged, the plurality of second chips 202 may include a logic chip and a memory chip.

In some embodiments, the second chip 202 includes a functional surface and a back surface that are opposite to each other. An integrated chip (not illustrated) is formed in the second chip 202. A pad (not illustrated) is arranged on the functional surface of the second chip 202. The pad is electrically connected to the integrated circuit. A protruded second solder bump 209 is formed on a surface of the pad of the second chip 202. In some embodiments, the second solder bump 209 may be a solder boss or includes a metal bump or a solder boss on a top surface of the metal bump. In some embodiments, the pad is made of one or more of aluminum, nickel, tin, tungsten, platinum, copper, titanium, chromium, tantalum, gold, silver, the material of the metal bump is one or more of aluminum, nickel, tin, tungsten, platinum, copper, titanium, chromium, tantalum, gold, silver, and the material of the solder bump is one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

In some embodiments, an underfill layer 211 may be filled between the second chip 202 and the lower surface of the first substrate 101. The underfill layer 211 may be made of a silicon-based resin material, a thermoplastic resin material, a heat-cured resin material, or an ultraviolet-cured resin material, and a process for forming the underfill layer 211 includes a glue dispensing process.

In some embodiments, a backside metallization layer 210 is further formed on the back surface of the second chip 202. The backside metallization layer 210 is favorable to improving the efficiency of heat dissipation, and may be bonded to the subsequently formed metal heat sink channel or enclosure heat sink structure. In some embodiments, the backside metallization layer 210 may be made of a thermally conductive metal, which may be one or more of aluminum, nickel, tin, tungsten, platinum, copper, titanium, chromium, tantalum, gold, or silver.

In some embodiments, a passive device 208 is further mounted onto the lower surface of the first substrate 101. The passive device 208 is electrically connected to a portion of the first trace 105 in the first substrate 101. The passive device 207 may be one or more of a resistor, a capacitor, an inductor, a converter, a taper, a matching network, a resonator, a filter, a mixer, or a switch.

In some embodiments, an interconnect bump 108 electrically connected to a portion of the lower pad 104 on the lower surface of the first substrate 101 is further formed on the lower surface of the first substrate 101. In some embodiments, the interconnect bump 108 may be a solder boss or includes a metal bump and a solder boss on a top surface of the metal bump. The metal bump is made of one or more of aluminum, nickel, tin, tungsten, platinum, copper, titanium, chromium, tantalum, gold, silver, and solder bumps on top surfaces of the metal bumps of one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony. In some other embodiments, the interconnect bump may be a metal ball or an interposer.

In some embodiments, still referring to FIG. 6, a thickness of the second chip 202 flip-mounted onto the lower surface of the first substrate 101 is less than a thickness of the interconnect bump 108 mounted onto the lower surface of the first substrate 101. In some other embodiments, the thickness of the second chip 202 flip-mounted onto the lower surface of the first substrate 101 is greater than the thickness of the interconnect bump 108 mounted onto the lower surface of the first substrate 101.

In some embodiments, referring to FIG. 7, the method further includes: providing a second substrate 102, wherein the second substrate 102 has an upper surface and a lower surface that are opposite to each other, and a second trace (not illustrated) is arranged in the second substrate 102, an upper pad and a lower pad (not illustrated) that are connected to the second trace being respectively arranged on the upper surface and the lower surface of the second substrate 102, and a metal heat sink channel 109 is defined in the second substrate 102; and mounting the second substrate 102 under the lower surface of the first substrate 101, wherein the upper pad on the upper surface of the second substrate 102 is soldered to the interconnect bump 108, and an upper surface of the metal heat sink channel 109 in the second substrate 102 is soldered to the backside metallization layer 210 on the back surface of the second chip 202.

The metal heat sink channel 109 is made of a metal. In one specific embodiment, the metal heat sink channel 109 may be made of one or more of aluminum, nickel, tin, tungsten, platinum, copper, titanium, chromium, tantalum, gold, or silver.

In some embodiments, when a thickness of the second chip 202 flip-mounted onto the lower surface of the first substrate 101 is greater than a thickness of the interconnection bump 108 mounted onto the lower surface of the first substrate 101, a heat sink opening (not illustrated) extending through the upper surface and the lower surface of the second substrate 102 is defined in the second substrate 102. When the second substrate 102 is mounted under the lower surface of the first substrate 101, and the upper pad on the upper surface of the second substrate 102 is soldered to the interconnect bump 108, the heat sink opening in the second substrate 102 exposes the backside metallization layer 210 on the back surface of the second chip 202.

In some embodiments, referring to FIG. 7, the method further includes: providing an enclosure heat sink structure 302, wherein the enclosure heat sink structure 302 is mounted onto the lower surface of the second substrate 102, and a portion of the enclosure heat sink structure 302 is soldered or attached to a lower surface of the metal heat sink channel 109 in the second substrate 102. In one specific embodiment, the enclosure heat sink structure 302 is soldered to the lower surface of the second substrate 102 and the lower surface of the metal heat sink channel 109 via several discrete solder bumps 110. In another specific embodiment, a portion of the enclosure heat sink structure 302 may be attached to the lower surface of the metal heat sink channel 109 in the second substrate 102 via a TIM layer.

In some embodiments, when a thickness of the second chip 202 flip-mounted onto the lower surface of the first substrate 101 is greater than a thickness of the interconnection bump 108 mounted onto the lower surface of the first substrate 101, a heat sink opening (not illustrated) extending through the upper surface and the lower surface of the second substrate 102 is defined in the second substrate 102. When the heat sink opening in the second substrate 102 exposes the backside metallization layer 210 on the back surface of the second chip 202, the enclosure heat sink structure 302 may include a protruded pin (not illustrated). The protruded pin extends through the heat sink opening and is soldered or attached to the backside metallization layer 210 on the back surface of the second chip 202.

In some embodiments, a size of the enclosure heat sink structure 302 may be less than, equal to, or greater than a size of the second substrate 102.

Some embodiments of the present disclosure provide a package structure. Referring to FIG. 7, the package structure includes:
a first substrate 101 having an upper surface and a lower surface that are opposite to each other, wherein at least one trench 106 is defined in the first substrate 101, the trench 106 extending through a portion of the upper surface of the first substrate 101;
a first chip 201 including a functional surface and a back surface that are opposite to each other, wherein the functional surface of the first chip 201 is mounted onto the upper surface of the first substrate 101 on a side of the trench 106, and the first chip 201 is electrically connected to the first substrate 101;
a heat sink lid 301 including a horizontal heat sink plate 303 and a first vertical pin 304 and at least one second vertical pin 305 that protrude from a surface of the horizontal heat sink plate 303, wherein a length of the second vertical pin 305 is greater than a length of the first vertical pin 304, the heat sink lid 301 is mounted onto the upper surface of the first substrate 101, a bottom surface of the first vertical pin 304 of the heat sink lid 301 is attached to the upper surface of the first substrate 101, a bottom end of the second vertical pin 305 of the heat sink lid 301 is buried in the corresponding trench 106, and a bottom surface of the horizontal heat sink plate 303 of the heat sink lid 301 is attached to the back surface of the first chip 201.

In some embodiments, the bottom surface of the first vertical pin 304 of the heat sink lid 301 is attached to the upper surface of the first substrate 101 via a thermal bonding adhesive 308, the bottom end of the second vertical pin 305 of the heat sink lid 301 is buried in the corresponding trench 106 via a second thermal bonding adhesive 309, and the bottom surface of the horizontal heat sink plate 303 of the heat sink lid 301 is attached to the back surface of the first chip via a third thermal bonding adhesive 307.

In some embodiments, at least one recess 306 (referring to FIG. 4) is defined in the bottom end of the second vertical pin 305. When the bottom end of the second vertical pin 305 of the heat sink lid 301 is buried in the corresponding trench 106 via the second thermal bonding adhesive 309, the bottom end of the second vertical pin 305 extends into the trench 106, and the second thermal bonding adhesive 309 wraps a side wall of the bottom end and a bottom surface of the second vertical pin 305 and fills the trench 106 and the recess 306.

In some embodiments, a first trace 105 is arranged in the first substrate 101, wherein an upper pad 103 and a lower pad 104 that are connected to the first trace 105 are respectively arranged on the upper surface and the lower surface of the first substrate 101, and the trench 106 exposes a top surface and/or a side surface of a portion of the first trace 105; and a first solder bump 204 protrudes from the functional surface of the first chip 201, wherein the first solder bump 204 is soldered to the upper pad 103 on the upper surface of the first substrate 101.

In some embodiments, one or a plurality of first chips 201 are arranged. When a plurality of first chips 201 are arranged, the plurality of first chips 201 have a same thickness or different thicknesses. When the plurality of first chips 201 have different thicknesses, the horizontal heat sink plate 303 of the heat sink lid 301 has varying thicknesses when contacting with the first chips 201 with different thicknesses.

In some embodiments, the package structure further includes: a second chip 202 including a functional surface and a back surface that are opposite to each other. A second solder bump 209 protrudes from the functional surface of the second chip 202. The functional surface of the second chip 202 is mounted onto the lower surface of the first substrate 101. The second solder bump 209 is soldered to the lower pad 104 on the lower surface of the first substrate 101.

In some embodiments, an interconnect bump 108 electrically connected to a portion of the lower pad 104 on the lower surface of the first substrate 101 is further formed on the lower surface of the first substrate 101, and a backside metallization layer 210 is formed on the back surface of the second chip 202; and the package structure further includes: a second substrate 102. The second substrate 102 has an upper surface and a lower surface that are opposite to each other, and a second trace (not illustrated) is arranged in the second substrate 102. An upper pad and a lower pad (not illustrated) that are electrically connected to the second trace are respectively arranged on the upper surface and the lower surface of the second substrate 102. A metal heat sink channel 109 or a heat sink opening (not illustrated) extending through the upper surface and the lower surface of the second substrate 102 is defined in the second substrate 102. The second substrate 102 is mounted under the lower surface of the first substrate 101. The upper pad on the upper surface of the second substrate 102 is soldered to the interconnect bump 108. An upper surface of the metal heat sink channel 109 in the second substrate 102 is soldered to the backside metallization layer 210 on the back surface of the second chip 202, or the heat sink opening in the second substrate 102 exposes the backside metallization layer 210 on the back surface of the second chip 202.

In some embodiments, the package structure further includes: an enclosure heat sink structure 302. The enclosure heat sink structure 302 is mounted onto the lower surface of the second substrate 102, and a portion of the enclosure heat sink structure 302 is soldered or attached to a lower surface of the metal heat sink channel 109 in the second substrate 102. Alternatively, the enclosure heat sink structure 302 includes a protruded pin (not illustrated). The protruded pin extends through the heat sink opening and is soldered or attached to the backside metallization layer 210 on the back surface of the second chip 202.

In addition, terms “comprise,” “include,” and variations thereof used herein in the text of the present disclosure are intended to define a non-exclusive meaning. It should be noted that the terms such as “first,” “second,” and the like in the specifications, claims and the accompanying drawings of the present disclosure are intended to distinguish different objects but are not intended to define a specific order or a definite time sequence. Unless otherwise clearly indicated in the context, it should be understood that the data used in this way can be interchanged under appropriate circumstances. In cases of no conflict, the embodiments and features in the embodiments of the present disclosure may be combined together. Further, in the above description, descriptions of well-known components and techniques are omitted so as not to unnecessarily obscure the inventive concepts of the present disclosure. In various embodiments of the present disclosure, the same or similar parts between the embodiments may be referenced to each other. In each embodiment, the portion that is different from other embodiments is concentrated and described.

Although the present disclosure has been disclosed above with reference to preferred embodiments, these embodiments are not intended to limit the present disclosure but illustrate the present disclosure. Without departing from the spirit and scope of the present disclosure, any person skilled in the art may make possible variations and modifications to the technical solutions based on the method and technical content disclosed herein in this literature. Therefore, any content without departing from the technical solutions of the present disclosure and any simple variation, equivalent replacement and modification made based on the technical essence of the present disclosure shall fall within the protection scope defined by the technical solutions of the present disclosure.

What is claimed is:

1. A method for forming a package structure, comprising:
providing a first substrate, wherein the first substrate has an upper surface and a lower surface that are opposite to each other, and at least one trench is defined in the first substrate, the trench extending through a portion of the upper surface of the first substrate;
providing a first chip;
mounting the first chip onto the upper surface of the first substrate on a side of the trench, wherein the first chip is electrically connected to the first substrate;
providing a heat sink lid, wherein the heat sink lid comprises a horizontal heat sink plate, and a first vertical pin and at least one second vertical pin that protrude from a surface of the horizontal heat sink plate, a length of the second vertical pin being greater than a length of the first vertical pin; and
mounting the heat sink lid onto the upper surface of the first substrate, wherein a bottom surface of the first vertical pin of the heat sink lid is attached to the upper surface of the first substrate, and a bottom end of the second vertical pin of the heat sink lid is buried in a corresponding trench.

2. The method according to claim 1, wherein the first chip comprises a functional surface and a back surface that are opposite to each other, wherein the functional surface of the first chip is mounted onto the upper surface of the first substrate, and a bottom surface of the horizontal heat sink plate of the heat sink lid is attached to the back surface of the first chip.

3. The method according to claim 2, wherein the bottom surface of the first vertical pin of the heat sink lid is attached to the upper surface of the first substrate via a thermal bonding adhesive, the bottom end of the second vertical pin of the heat sink lid is buried in the corresponding trench via a thermal bonding adhesive, and the bottom surface of the horizontal heat sink plate of the heat sink lid is attached to the back surface of the first chip via a thermal bonding adhesive.

4. The method according to claim 1, wherein a plurality of trenches are formed, wherein the plurality of trenches are distributed in the first substrate on a side or around a mounting region of the first chip; and wherein the number of the second vertical pin is equal to the number of the plurality of trenches.

5. The method according to claim 1, wherein at least one recess is defined in a bottom end of the second vertical pin; and wherein when the bottom end of the second vertical pin of the heat sink lid is buried in the corresponding trench via a thermal bonding adhesive, the bottom end of the second vertical pin extends into the trench, and the thermal bonding adhesive wraps a side wall of the bottom end and a bottom surface of the second vertical pin and fills the trench and the recess.

6. The method according to claim 1, wherein a difference value between the length of the first vertical pin and the length of the second vertical pin is equal to or less than a depth of the trench.

7. The method according to claim 1, wherein a first trace is arranged in the first substrate, wherein an upper pad and a lower pad that are connected to the first trace are respectively arranged on the upper surface and the lower surface of the first substrate, and the trench exposes a top surface or a side surface of a portion of the first trace; and a first solder bump protrudes from a functional surface of the first chip, wherein the first solder bump is soldered to the upper pad on the upper surface of the first substrate.

8. The method according to claim 7, further comprising: providing a second chip, wherein the second chip comprises a functional surface and a back surface that are opposite to each other, a second solder bump protruding from the functional surface of the second chip; and mounting the functional surface of the second chip onto the lower surface of the first substrate, and soldering the second solder bump to the lower pad on the lower surface of the first substrate.

9. The method according to claim 7, wherein the portion of the first trace exposed by the trench is connected to the second vertical pin of the heat sink lid via a thermal bonding adhesive.

10. The method according to claim 8, wherein an interconnect bump electrically connected to a portion of the lower pad on the lower surface of the first substrate is further formed on the lower surface of the first substrate, and a backside metallization layer is formed on the back surface of the second chip; and the method further comprises: providing a second substrate, wherein the second substrate has an upper surface and a lower surface that are opposite to each other, and a second trace is arranged in the second substrate, an upper pad and a lower pad that are electrically connected to the second trace being respectively arranged on the upper surface and the lower surface of the second substrate, and a metal heat sink channel or a heat sink opening extending through the upper surface and the lower surface of the second substrate is defined in the second substrate; and mounting the second substrate under the lower surface of the first substrate, wherein the upper pad on the upper surface of the second substrate is soldered to the interconnect bump, and an upper surface of the metal heat sink channel in the second substrate is soldered to the backside metallization layer on the back surface of the second chip, or the heat sink opening in the second substrate exposes the backside metallization layer on the back surface of the second chip.

11. The method according to claim 10, further comprising: providing an enclosure heat sink structure, wherein the enclosure heat sink structure is mounted onto the lower surface of the second substrate, and a portion of the enclosure heat sink structure is soldered or attached to a lower surface of the metal heat sink channel in the second substrate; or the enclosure heat sink structure comprises a protruding pin, the protruding pin extending through the heat sink opening and being soldered or attached to the backside metallization layer on the back surface of the second chip.

12. A package structure, comprising:
a first substrate having an upper surface and a lower surface that are opposite to each other, wherein at least one trench is defined in the first substrate, the trench extending through a portion of the upper surface of the first substrate;
a first chip mounted onto the upper surface of the first substrate on a side of the trench, wherein the first chip is electrically connected to the first substrate;
a heat sink lid comprising a horizontal heat sink plate and a first vertical pin and at least one second vertical pin that protrude from a surface of the horizontal heat sink plate, wherein a length of the second vertical pin is greater than a length of the first vertical pin, the heat sink lid is mounted onto the upper surface of the first substrate, a bottom surface of the first vertical pin of the heat sink lid is attached to the upper surface of the first substrate, and a bottom end of the second vertical pin of the heat sink lid is buried in a corresponding trench.

13. The package structure according to claim 12, wherein the first chip comprises a functional surface and a back surface that are opposite to each other, wherein the functional surface of the first chip is mounted onto the upper surface of the first substrate, and a bottom surface of the horizontal heat sink plate of the heat sink lid is attached to the back surface of the first chip.

14. The package structure according to claim 13, wherein the bottom surface of the first vertical pin of the heat sink lid is attached to the upper surface of the first substrate via a thermal bonding adhesive, the bottom end of the second vertical pin of the heat sink lid is buried in the corresponding trench via a thermal bonding adhesive, and the bottom surface of the horizontal heat sink plate of the heat sink lid is attached to the back surface of the first chip via a thermal bonding adhesive.

15. The package structure according to claim 12, wherein a plurality of trenches are formed, wherein the plurality of trenches are distributed in the first substrate on a side or around a mounting region of the first chip; and wherein the number of the first vertical pin is equal to the number of the plurality of trenches.

16. The package structure according to claim 12, wherein at least one recess is defined in a bottom end of the second vertical pin; and wherein when the bottom end of the second vertical pin of the heat sink lid is buried in the corresponding trench via a thermal bonding adhesive, the bottom end of the second vertical pin extends into the trench, and the thermal bonding adhesive wraps a side wall of the bottom end and a bottom surface of the second vertical pin and fills the trench and the recess.

17. The package structure according to claim 12, wherein a first trace is arranged in the first substrate, wherein an upper pad and a lower pad that are connected to the first trace are respectively arranged on the upper surface and the lower surface of the first substrate, and the trench exposes a top surface or a side surface of a portion of the first trace; and a first solder bump protrudes from a functional surface of the first chip, wherein the first solder bump is soldered to the upper pad on the upper surface of the first substrate.

18. The package structure according to claim 16, further comprising: a second chip, wherein the second chip comprises a functional surface and a back surface that are opposite to each other, wherein a second solder bump protrudes from the functional surface of the second chip, and the functional surface of the second chip is mounted onto the lower surface of the first substrate, the second solder bump being soldered to the lower pad on the lower surface of the first substrate.

19. The package structure according to claim 18, wherein an interconnect bump electrically connected to a portion of the lower pad on the lower surface of the first substrate is further formed on the lower surface of the first substrate, and a backside metallization layer is formed on the back surface of the second chip; and the package structure further comprises: a second substrate, wherein the second substrate has an upper surface and a lower surface that are opposite to each other, and a second trace is arranged in the second substrate, an upper pad and a lower pad that are electrically connected to the second trace being respectively arranged on the upper surface and the lower surface of the second substrate, and a metal heat sink channel or a heat sink opening extending through the upper surface and the lower surface of the second substrate is defined in the second substrate; and the second substrate is mounted under the lower surface of the first substrate, wherein the upper pad on the upper surface of the second substrate is soldered to the interconnect bump, and an upper surface of the metal heat sink channel in the second substrate is soldered to the backside metallization layer on the back surface of the second chip, or the heat sink opening in the second substrate exposes the backside metallization layer on the back surface of the second chip.

20. The package structure according to claim 18, further comprising: an enclosure heat sink structure, wherein the enclosure heat sink structure is mounted onto the lower surface of the second substrate, and a portion of the enclosure heat sink structure is soldered or attached to a lower surface of the metal heat sink channel in the second substrate; or the enclosure heat sink structure comprises a protruding pin, the protruding pin extending through the heat sink opening and being soldered or attached to the backside metallization layer on the back surface of the second chip.
